(19) United States
(12) Patent Application Publication
(10) Pub. No.: US 2020/0411414 A1
(43) Pub. Date: Dec. 31, 2020

(54) THROUGH SEMICONDUCTOR VIA STRUCTURE WITH REDUCED STRESS PROXIMITY EFFECT

(71) Applicant: Conversant Intellectual Property Management Inc., Ottawa (CA)

(72) Inventor: Soogeun Lee, Ottawa (CA)

(21) Appl. No.: 17/007,799

(22) Filed: Aug. 31, 2020

Related U.S. Application Data
(63) Continuation of application No. 14/312,052, filed on Jun. 23, 2014.
(60) Provisional application No. 61/856,947, filed on Jul. 22, 2013.

(51) Int. Cl. H01L 23/48; H01L 21/768

(52) U.S. Cl. CPC H01L 23/481; H01L 21/76898; H01L 2924/0002; H01L 21/76816; H01L 21/76843

(57) ABSTRACT

An integrated circuit device and associated fabrication process are disclosed for forming a through semiconductor via (TSV) conductor structure in a semiconductor substrate with active circuitry formed on a first substrate surface where the TSV conductor structure includes multiple small diameter conductive vias extending through the first substrate surface and into the semiconductor substrate by a predetermined depth and a large diameter conductive via formed to extend from the multiple small diameter conductive vias and through a second substrate surface opposite to the first substrate surface.

### CROSS-REFERENCE TO RELATED APPLICATIONS

This application is a continuation of U.S. patent application Ser. No. 14/312,052 filed on Jun. 23, 2014 which claims the benefit of U.S. Provisional Application No. 61/856,947, filed Jul. 22, 2013. The above-identified application is herein incorporated by reference in its entirety.

### BACKGROUND OF THE INVENTION

### Field of the Invention

The present invention is directed in general to integrated circuit devices and methods for manufacturing same. In one aspect, the present invention relates to through silicon via (TSV) structures used with integrated circuit devices.

### Description of the Related Art

As semiconductor devices increasingly include high density circuitry and component connection structures, there is increasing interest in routing signals and/or power lines through the silicon wafer or die to support the development of three-dimensional (3D) integrated circuits which achieve higher device density by bonding two or more layers of circuit substrates or wafers into a stacked die architecture. In support of such stacked arrangements, through semiconductor via (TSV) structures—also referred to as through substrate via structures and through silicon via structures—are formed to provide a vertical electrical connection via (Vertical Interconnect Access) connectors passing completely through a silicon wafer or die. TSVs are a high performance technique used to create 3D packages and 3D integrated circuits, compared to alternatives such as package-on-package, because the density of the vias is substantially higher, and because the length of the connections is shorter. However, the materials used to form conventional TSV structures (e.g., copper) can create structural stress on the surrounding semiconductor substrate which can alter the electron and hole mobility in the semiconductor substrate areas near the TSV structure, thereby introducing undesirable transistor variations which can impair the performance of integrated circuit devices formed near the TSV structure. The magnitudes of the stresses are most pronounced near the TSV structure, and fall off with increasing distance.

To illustrate this stress effect, reference is made to FIG. 1 which shows a plan view 1 of a semiconductor substrate region 50 (e.g., monocrystalline silicon) containing a TSV structure 52 formed with one or more suitably conductive materials (e.g., copper) to fill a vertical via opening in the substrate which is lined with an insulator layer 51 formed with a suitable insulating material. While the insulator layer 51 around the TSV structure 52 does help reduce the stresses introduced into the semiconductor substrate 50 by the TSV structure 52, significant strain remains that is introduced by the different coefficients of thermal expansion between the TSV structure 52 and surrounding semiconductor region 50, inducing a TSV stress proximity effect in the semiconductor substrate area surrounding the TSV 52. This TSV stress proximity effect, which has a range of several microns, can produce enhancement or degradation of the current, and can lead to structural reliability concerns, such as cracking and delamination. One conventional approach for avoiding such problems is to define an exclusion zone or structure 53 around each TSV structure 52 so that transistors are not located within the exclusion zone 53. For example, a typical 5 μm diameter TSV structure 52 may have an exclusion zone 53 that extends 5-10 μm on each side, resulting in an unusable area for each TSV structure of 180-500 μm². With multiple TSV structures formed on a single chip, this approach can result in enormous amounts of unused substrate space (e.g., 1.8-5 mm² of unused space on a chip with 10,000 TSV structures).

### BRIEF DESCRIPTION OF THE DRAWINGS

The present invention may be understood, and its numerous objects, features and advantages obtained, when the following detailed description is considered in conjunction with the following drawings, in which:

FIG. 1 illustrates a simplified plan view of a semiconductor substrate region containing a conventional TSV structure;

FIG. 2 illustrates a simplified front side plan view of a semiconductor substrate region in which a TSV structure is formed in accordance with selected embodiments of the present disclosure;

FIG. 3 illustrates a partial cross-sectional view of a semiconductor substrate in which a TSV structure is formed with a plurality of top TSV conductors and a single bottom TSV conductor to provide a compact exclusion area around the top TSV conductors in accordance with selected embodiments of the present disclosure;

FIGS. 4-14 show an example semiconductor device during successive phases of a fabrication sequence in which a TSV structure is formed with a plurality of top TSV conductors and a single bottom TSV conductor to provide a compact exclusion area around the top TSV conductors in accordance with selected embodiments of the present disclosure; and

FIG. 15 illustrates an example process flow diagram of a fabrication sequence for fabricating a TSV structure in accordance with selected embodiments of the present disclosure.

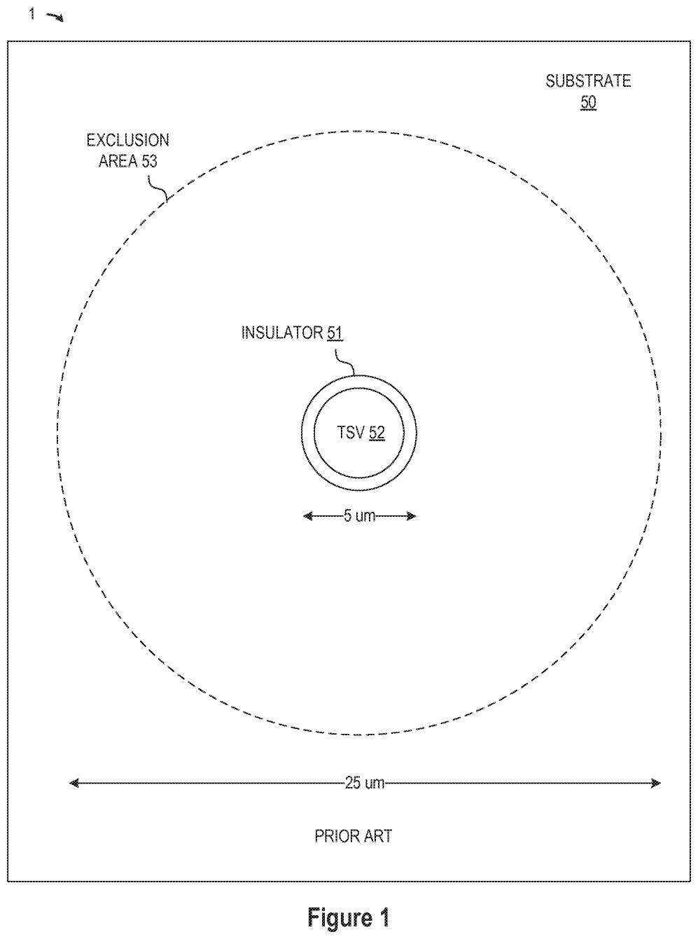

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A compact through semiconductor via structure with reduced stress proximity effect and associated fabrication processes are disclosed in which a TSV structure includes one or more smaller TSV conductors formed in the top or device side portion of the substrate and one or more larger TSV conductor formed in the bottom portion of the substrate to provide a compact exclusion area around the smaller TSV conductor(s) at the device side of the substrate. By forming the one or more smaller TSV conductors on the top to extend only partway through the substrate, the size of the exclusion zone area at the device side of the substrate may be reduced without imposing the processing costs and technical challenges of increasing the aspect ratio for etching a smaller vertical TSV via opening the entire length of the substrate, such as etching, gap filling etc. By forming a single larger TSV conductor in the bottom or backside portion of the substrate, the aspect ratio for the smaller vertical TSV via openings may be maintained since they extend only partway through the substrate. In selected embodiments for fabricating a TSV structure having reduced exclusion zone areas around the top or device side portion of the substrate, one or more relatively small TSV conductors are formed by selectively etching a topside portion of a wafer substrate to define one or more relatively small via openings having a first aspect ratio which extend partway through the wafer substrate. In the relatively small via opening(s), an insulation lining layer is formed along with one or more conductive fill material layers (e.g., metal copper) to form a first TSV structure portion having one or more smaller TSV conductors to provide a compact exclusion area around the first TSV structure portion at the device side of the substrate. When forming the conductive fill material layers, one or more conductive interconnects to active circuits formed on the wafer substrate may be formed. After forming the smaller TSV conductor(s) on the topside portion of the wafer substrate, one or more aligned backside TSV conductors are formed in electrical contact with the smaller TSV conductor(s), such as by selectively etching a backside portion of the wafer substrate to define a single via opening having a second, smaller aspect ratio to extend through the wafer substrate and expose the smaller TSV conductor(s). In the single via opening, an insulation lining layer is selectively formed on the sidewalls, and one or more conductive fill material layers (e.g., metal copper) are formed in the single via opening to form a second TSV structure portion in electrical contact with the smaller TSV conductor(s). In this way, the first TSV structure portion is formed (e.g., by patterning, etching and filling relatively small via openings) in the wafer substrate in alignment with the second TSV structure portion to provide electrical and/or thermal via conduits through the wafer substrate.

In this disclosure, an improved system, apparatus, and fabrication method are described for fabricating one or more TSV structures in a wafer or substrate that address various problems in the art where various limitations and disadvantages of conventional solutions and technologies will become apparent to one of skill in the art after reviewing the remainder of the present application with reference to the drawings and detailed description provided herein. For example, there are challenges with reducing the size of exclusion areas or structures around each TSV structure, not only from lost chip space in each exclusion area/structure, but also from the technical challenges imposed by etching TSV openings with increased aspect ratios to extend completely through the wafer or substrate. Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a semiconductor device without including every device feature or geometry in order to avoid limiting or obscuring the present invention. Such descriptions and representations are used by those skilled in the art to describe and convey the substance of their work to others skilled in the art. In addition, although specific example materials are described herein, those skilled in the art will recognize that other materials with similar properties can be substituted without loss of function. It is also noted that, throughout this detailed description, certain materials will be formed and removed to fabricate the semiconductor structure. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art of how to make or use the present invention.

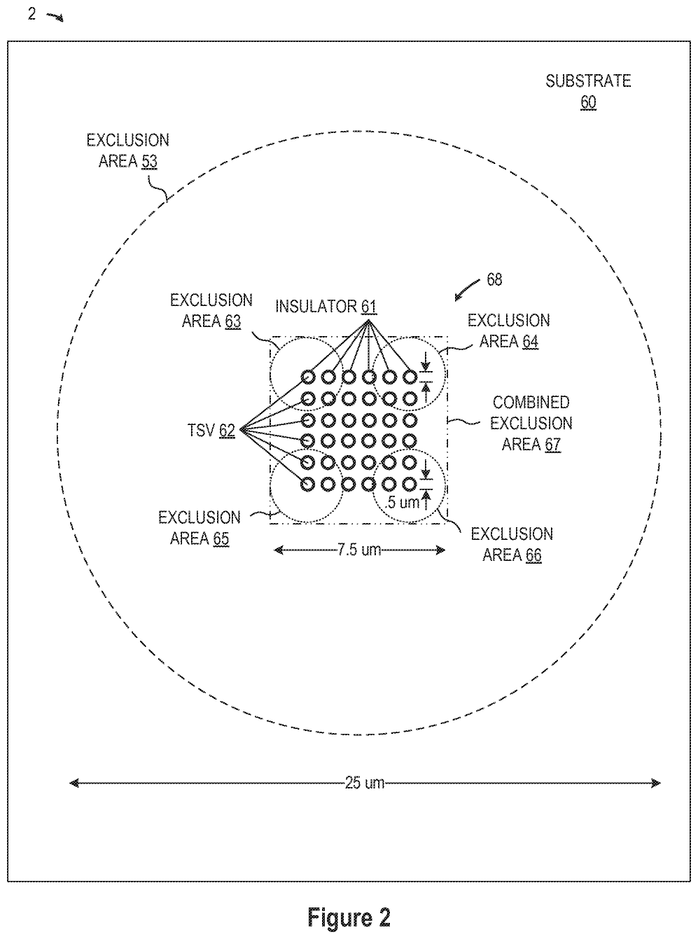

Turning now to FIG. 2, there is shown a simplified front side plan view 2 of a semiconductor substrate region 60 (e.g., monocrystalline silicon, silicon germanium, or the like) in which a TSV structure 68 is formed with a plurality of top TSV conductors 62 having insulating liner layers 61 formed in the top or device side portion of the substrate 60 and a single bottom TSV conductor formed in the bottom portion of the substrate (not shown). Each of the top TSV conductors 62 may be formed with one or more suitably conductive materials (e.g., copper) to fill a vertical via opening in the substrate which is lined with an insulator layer 61 (e.g., silicon oxide, silicon nitride, silicon oxynitride, etc.). While any desired number, dimensions, or pattern may be used, in selected embodiments, the top TSV conductors 62 may be formed as matrix (e.g., 6×6) of TSV conductors, each having a diameter (e.g., 0.5 μm) that is a predetermined fraction (e.g., 1/10) of the TSV design rule. The resulting exclusion area for each individual TSV structure 62 is correspondingly reduced in size, as illustrated with the reduced exclusion areas 63-66 for the four corner TSV structures 62. Assuming that each exclusion area extends on each side of the TSV structure 62 by a distance of twice the diameter of the TSV structure 62, the resulting combined or cumulative exclusion area 67 is reduced by a predetermined fraction from the size of the conventional exclusion areas 53. In an example embodiment where each of the top TSV conductors 62 has a diameter of 0.5 μm, the total area of the combined 7.5 μm×7.5 μm exclusion zone 67 is approximately 56 μm², which is approximately 1/10 of the size of the conventional exclusion area 53 (e.g., πr²=π(25/2)²=491 μm²). Again, the size and the number of the top TSV conductors 62 can be varied depending on the conductivity requirement of the TSV structure 68.

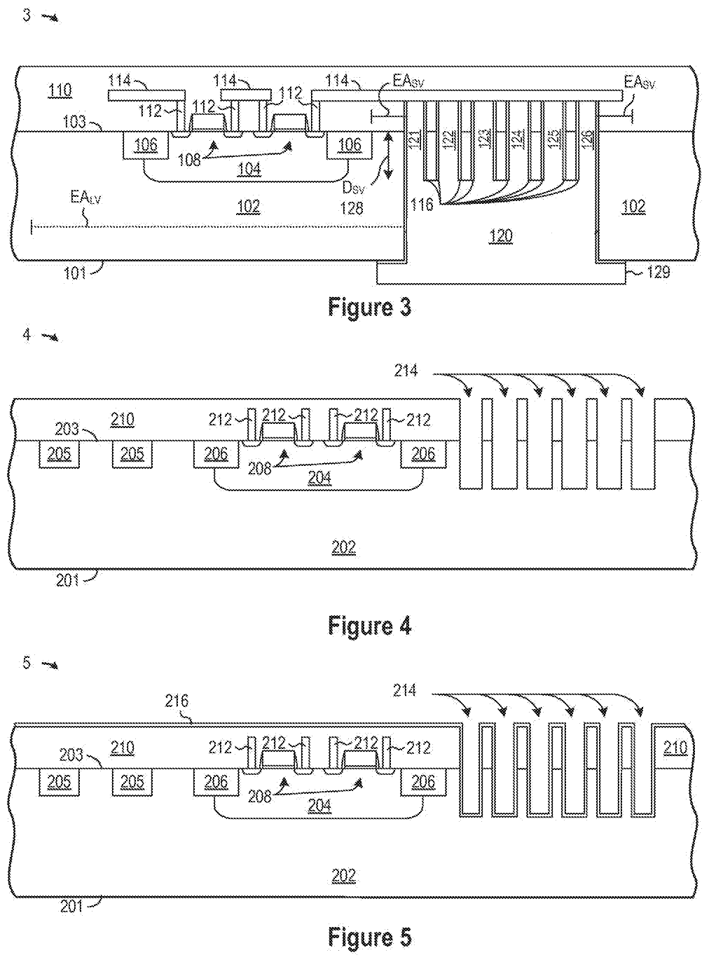

Referring now to FIG. 3, there is shown a partial cross-sectional view of a semiconductor device having a substrate 102 and planarized interlayer dielectric layer 110 in which a TSV structure 129 is formed with a plurality of top TSV conductors 121-126 and a single bottom TSV conductor 120 to provide a compact exclusion area EA around the top TSV conductors 121-126. The substrate 102 may be formed as bulk semiconductor substrate, semiconductor-on-insulator (SOI) type substrate, or other substrate having a first or bottom surface 101 and a second or top surface 103. On the top surface 103, one or more active circuits are formed with transistor devices 108 or other circuitry formed in one or more well regions 104 which may be isolated with shallow trench isolation (STI) regions 106. To connect one or more of the transistor devices 108 to a power or signal conductor, one or more contact structures 112 and metal interconnect lines 114 are formed and electrically connected to the TSV structure 129 which extends from the first or bottom surface 101 through the second or top surface 103 in the substrate 102. As illustrated, the TSV structure 129 includes a plurality of small diameter TSV conductors 121-126 formed in the top or device side portion of the substrate 102 and a single larger diameter TSV conductor 120 formed in the bottom portion of the substrate 102. In selected embodiments, each of the smaller diameter TSV conductors (e.g., 122) is formed with one or more suitable conductor materials (e.g., a metal barrier layer and electroplated copper layer) which are surrounded by an insulator liner layer 116 formed with a suitable insulating material (e.g., silicon oxide, silicon nitride, silicon oxynitride, or the like). In similar fashion, the larger diameter TSV conductor 120 is formed with one or more suitable conductor materials which are surrounded by an insulator liner layer formed with a suitable insulating material. By forming the smaller diameter TSV conductors 121-126 to extend only partially through the substrate 102, the aspect ratio of the TSV via opening etch process used to form the smaller diameter TSV conductors 121-126 may be maintained since the TSV via openings need not extend through the entire length of the substrate 102. This is accomplished by forming the larger diameter TSV conductor 120 in the bottom or backside portion of the substrate 102 to electrically contact the bottom of the smaller diameter TSV conductors 121-126. In addition to limiting the aspect ratio requirements for forming the top TSV conductors 121-126, the smaller diameter TSV conductors 121-126 also reduce the exclusion area (EA) around the TSV structure 129 at the device side substrate surface, allowing for a more compact, higher density arrangement of the TSV structure 129 and active circuit transistor devices 108. As will be appreciated, the lateral extent of an exclusion area for a TSV structure having the same diameter as the larger TSV conductor 120 would prevent the TSV structure from being located as close to the active circuit transistor devices 108.

The resulting difference in exclusion areas and device compactness is visually indicated in FIG. 3 where the exclusion area based on the small via TSV conductor (EA_{SV}) (e.g., 121) allows the TSV structure 129 to be located much closer to the active circuit transistor devices 108 than would be possible with an exclusion area based on the large via TSV conductor (EA_{LV}). As will be appreciated, any structural stress effects at the active device surface 103 that would be induced by the larger TSV conductor 120 are reduced or eliminated by forming the larger TSV conductor 120 below the active device surface 103 by a minimum specified depth, such as the depth of the small diameter TSV conductors 121-126 (D_{SV}).

FIGS. 4-14 show an example semiconductor device during successive phases of a fabrication sequence in which a TSV structure is formed with a plurality of top TSV conductors and a single bottom TSV conductor to provide a compact exclusion area around the top TSV conductors in accordance with selected embodiments of the present disclosure. Starting with FIG. 4, there is shown a partial cross-sectional view of a first example semiconductor device or structure 4 formed on a substrate 202 having a first or bottom surface 201 and a second or top surface 203. Though example structures, well, and layer regions in the substrate 202 are illustrated in simplified form with straight lines and curved or corner regions, it will be appreciated that the actual profile(s) for the different structures, well, and layer regions will not necessarily conform to simplified depictions, but will instead depend on the specific fabrication process(es) used. For example, the various well regions may have a curved junction profile reflecting the implantation and heating steps used in the formation of same. In addition, the depicted device structures may be formed with different semiconductor materials having P-type conductivity and N-type conductivity. With the P-type materials, the dopant concentrations vary from lowest dopant concentrations (P-), higher dopant concentration (P), even higher dopant concentration (P+), and the highest dopant concentration (P++). Similarly, the dopant concentrations for the N-type materials vary from lowest dopant concentrations (N), higher dopant concentration (N+), and the highest dopant concentration for (N++).

In the semiconductor structure 4, the depicted substrate 202 may be formed as a bulk semiconductor substrate, semiconductor-on-insulator (SOI) type substrate or other semiconductor substrate material in which one or more additional semiconductor layers and/or well regions are formed using epitaxial semiconductor growth and/or selective doping techniques as described more fully hereinbelow. In an upper portion of the substrate 202, a plurality of shallow trench isolation (STI) structures 206 are formed that divide the substrate 202 into separate regions to provide isolated active circuit regions. In addition, one or more STI structures 205 may be formed in the upper portion of the substrate 202 to provide one or more front side alignment marks for use during backside formation of the TSV structures as described herein. As will be appreciated, the STI structures 205, 206 may be formed using any desired technique, such as selectively etching openings in the substrate 202 using a patterned mask or photoresist layer (not shown), depositing a dielectric layer (e.g., oxide) to fill the opening, and then polishing the deposited dielectric layer until planarized with the remaining substrate 202. Any remaining unetched portions of the patterned mask or photoresist layer(s) are stripped. As will be appreciated, the STI structures 205, 206 may be formed in other ways in other embodiments.

The upper portions of substrate 202 may also include one or more active substrate wells or layers 204 between the STI regions 206 that are formed by selectively implanting or diffusing appropriate polarity impurities into the substrate 202. As will be appreciated, the dopant type used to form the active well regions 205 will depend on whether the transistors formed in each area are n-type or p-type devices. If desired, one or more additional deep well regions (not shown) may be formed to isolate the active well regions 204, such as by selectively implanting or diffusing appropriate polarity impurities. Without belaboring the details, one or more active circuits or transistor devices 208 are formed in the active well regions 204 and encapsulated with one or more interlayer dielectric layers 210. For example, the active circuits or transistor devices 208 may be formed using any desired sequence of fabrication steps to define one or more patterned gate electrodes with sidewall implant spacers and one or more source/drain regions, and may include one or defined electrically conductive contact structures 212 for electrically connecting the source/drain regions and/or gate electrodes to power or signal lines. Over the active circuits or transistor devices 208 and electrically conductive contact structures 212, the encapsulating interlayer dielectric layers 210 may be formed using any desired technique, such as by depositing and polishing a first pre-metal or interlayer dielectric layer or stack to a thickness that is greater than the height of the transistor devices 208 and electrically conductive contact structures 212.

After forming a planarized interlayer dielectric layers 210, a plurality of relatively small TSV via holes 214 are formed in the planarized interlayer dielectric layers 210 and through the front side of the wafer substrate 202 to a predetermined depth using any desired pattern and etch technique. For example, a patterned photoresist layer or etch mask (not shown) on the planarized interlayer dielectric layers 210 and anisotropic etch process may be applied to selectively etch or remove portions of at least the planarized interlayer dielectric layers 210 and substrate 202 to form a patterned plurality of trench openings 214. Any desired patterning and anisotropic etching techniques may be used to form the patterned trench openings 214, including a dry etching process such as reactive-ion etching, ion beam etching, plasma etching or laser etching, a wet etching process wherein a chemical etchant is employed or any combination thereof. In an example embodiment, a patterned layer of photoresist and etch mask (not shown) may be used to define and etch down to the substrate 202 by removing exposed portions of the planarized interlayer dielectric layers 210. After the hardmask etch process, the photoresist is stripped (e.g., with an ash/piranha process), and one or more deep trench etches are performed to etch down to into the substrate 202 by a predetermined distance, such as by applying a timed etch process. Though not illustrated to scale in the figures, it will be appreciated that the trench etch process(es) may be controlled so that each of the patterned trench openings 214 has a predetermined depth-to-diameter ratio or aspect ratio. For example, with an aspect ratio of 10, each TSV hole is approximately 10 times as deep as the diameter of the TSV hole. In these embodiments, the aspect ratio of the patterned trench openings 214 is within the range of International Technology Roadmap for Semiconductors (ITRS).

FIG. 5 illustrates processing of the semiconductor structure 5 subsequent to FIG. 4 after forming an insulator layer 216 on at least the sidewalls of the patterned plurality of trench openings 214. In selected embodiments, the insulator layer 216 may be formed by depositing a conformal dielectric liner layer on top of planarized interlayer dielectric layers 210 and on the bottom and sidewall surfaces of the trench openings 214 using chemical vapor deposition (CVD), plasma-enhanced chemical vapor deposition (PECVD), physical vapor deposition (PVD), atomic layer deposition (ALD), or any combination(s) of the above. In selected embodiments, the insulator layer 216 may be formed by a low temperature PECVD or ALD process to a predetermined final thickness in the range of 1-100 Angstroms (e.g., 5-30 Angstroms), though other thicknesses may be used. A suitable dielectric material for the insulator layer 216 is silicon oxide, silicon nitride, silicon oxynitride, or the like. As formed, the insulator layer 216 will electrically isolate the finally formed TSV structure from the semiconductor substrate 202.

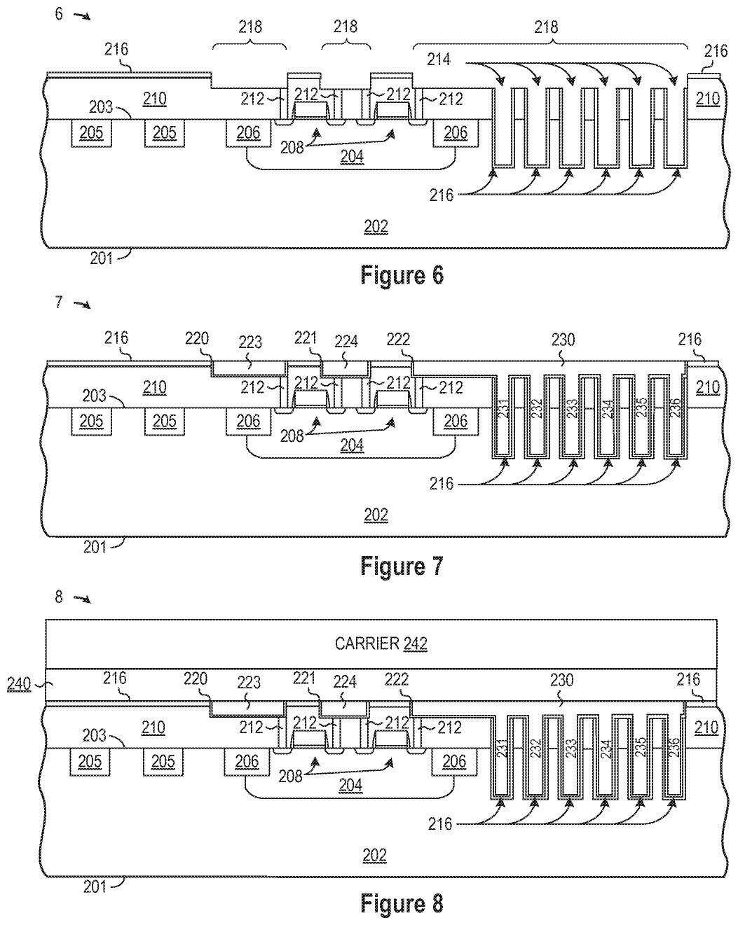

FIG. 6 illustrates processing of the semiconductor structure 6 subsequent to FIG. 5 after one or more metal trench openings 218 are formed through the insulator layer 216 and planarized interlayer dielectric layers 210 to overlap with and expose the electrically conductive contact structures 212 and to thin or reduce the planarized interlayer dielectric layer 210 formed in the region of the patterned trench openings 214. While any trench etch process may be used, in selected example embodiments, a patterned photoresist layer and/or etch mask (not shown) may be formed on the insulator layer 216 with defined openings over the contact structures 212 and patterned trench openings 214. With the patterned photoresist/etch mask in place, one or more anisotropic etch processes, such as an RIE etch, may be applied to define a first metal trench pattern 218 which exposes the contact structures 212 by selectively etching or removing exposed portions of at least the insulator layer 216 and planarized interlayer dielectric layers 210. A sacrificial spin-on-dielectric or polymer may be used to protect the insulator layer 216 during the RIE process for forming the trench pattern 218.

FIG. 7 illustrates processing of the semiconductor structure 7 subsequent to FIG. 6 after forming a plurality of first metal conductor structures 220-221, 223-224 and small diameter TSV conductor structures 222, 230-236 in the metal trench opening(s) 218 with one or more suitable conductor materials. In selected embodiments, the small diameter TSV conductor structures may be formed by first depositing one or more conductive metal barrier layers as a liner layer 220-222 (e.g., cobalt, ruthenium, tantalum, tantalum nitride, ruthenium nitride, indium oxide, tungsten nitride, titanium nitride, ruthenium tantalum nitride, or any combination of the foregoing, such as Ta/TaN or Ta/TiN) in the metal trench opening(s) 218 using CVD, PECVD, PVD, ALD, MBD, or any combination(s) thereof to a predetermined thickness in the range of 1-100 Angstroms (e.g., 5-30 Angstroms), though other materials and thicknesses may be used. As formed, the metal barrier liner layer 220-222 covers the remaining insulator layer 216 on the planarized interlayer dielectric layer(s) 210 and on the bottom and sidewall surfaces of the trench openings 214, 218. On the metal barrier liner layer 220-222, one or more layers of conductive metal material 223-224, 230-236 may be formed and planarized to fill the trench openings 214, 218, such as by forming one or more layers of suitable conductive material (e.g., copper) using CVD, PECVD, sputtering, PVD, electro-plating, electro-less plating, or the like, followed by chemical mechanical polish (CMP) planarization. The resulting planarized conductor layers 220-224, 230-236 may define one or more first metal contacts 220/223, 221/224 that are formed in electrical contact with one or more contact structures 212 over the transistor devices 208. The same sequence simultaneously forms a first TSV conductor structure having a plurality of conductor fingers 222, 231-236 extending from a shared metal contact layer 222, 230 that is formed in electrical contact with one or more contact structures 212 over the transistor devices 208.

FIG. 8 illustrates processing of the semiconductor structure 8 subsequent to FIG. 7 after forming one or more conductive interconnect and passivation layers 240 along with a carrier layer 242. Though illustrated in simplified form as a single planarized interlayer dielectric layer 210 that is formed over the wafer structure to cover the first metal contacts and small diameter TSV conductor structures 220-224, 230-236, it will be appreciated that the interconnect and passivation layers 240 may include one or more conductive interconnect layers and conductive via structures selectively formed in one or more planarized dielectric layers, such as by using a damascene copper interconnect fabrication sequence. For example, a first interlayer dielectric layer (e.g., silicon oxide) is patterned with open trenches where a copper conductor layer will be formed. After depositing a copper layer on the first interlayer dielectric layer to overfill the trenches and any exposed via openings, a CMP process removes the copper extending above the top of the insulating layer and leaves copper in the trenches to define a patterned conductor layer. This process may be repeated with additional interlayer dielectric layers and polished copper infill layers as desired. On the conductive interconnect and passivation layers 240, a temporary carrier layer 242 is formed, such as by bonding the conductive interconnect and passivation layers 240 to a temporary glass carrier layer 242 which may be subsequently thinned.

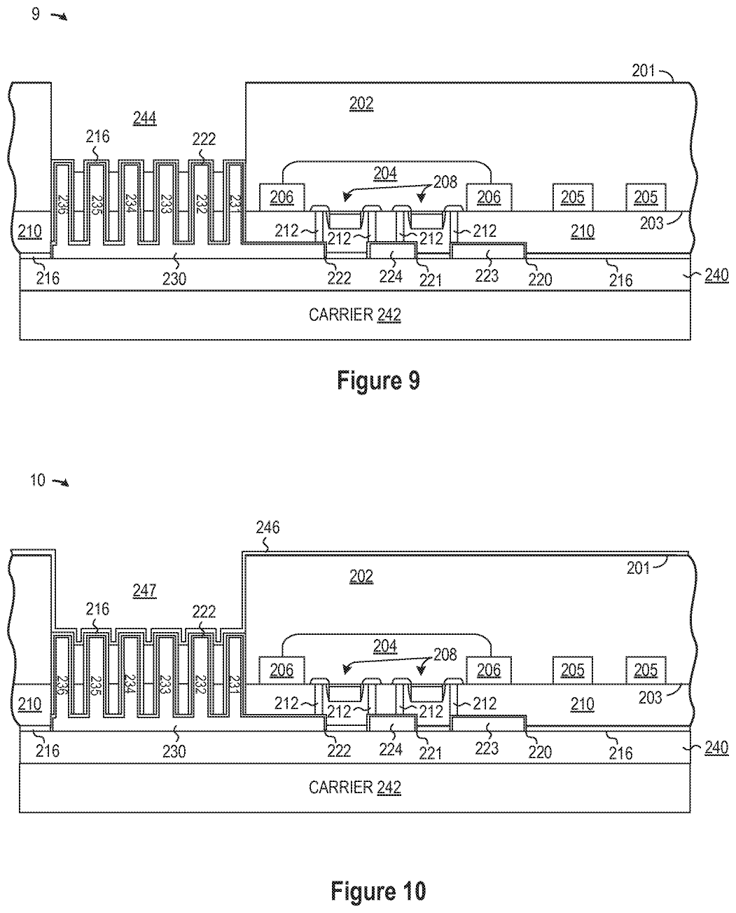

FIG. 9 illustrates processing of the semiconductor structure 9 subsequent to FIG. 8 after being flipped over to form a larger TSV structure on the backside 201 of the semiconductor structure that is aligned for thermal or electrical connection with the small diameter TSV conductor structures 222, 230-236. The backside processing begins by forming one or more relatively large TSV via holes 244 through the first surface 201 of the semiconductor substrate 202 to a predetermined depth using any desired pattern and etch technique. For example, a photoresist layer or etch mask (not shown) patterned on the first surface 201 of the semiconductor substrate 202 may be used with an anisotropic etch process to selectively etch or remove portions 244 of the semiconductor substrate 202 to expose a peripheral portion of the previously formed small diameter TSV conductor structures 222, 231-236. Any desired patterning and anisotropic etching techniques may be used to form the patterned trench openings 244, including a dry etching process such as deep reactive-ion etching, ion beam etching, plasma etching or laser etching, a wet etching process wherein a chemical etchant is employed or any combination thereof. In an example embodiment, a patterned layer of photoresist and etch mask (not shown) may be used to define and etch down to the insulator layer 216 formed on peripheral end portions of the conductor fingers 222, 231-236 by removing exposed portions of the substrate 202. The previously-formed insulator 216 helps improve process margin when etching the larger TSV via hole(s) 244 by providing an etch stop layer for the deep reactive-ion silicon etch so that the etch process does not directly touch the small diameter TSV conductor structures 222, 231-236.

FIG. 10 illustrates processing of the semiconductor structure 10 subsequent to FIG. 9 after forming an insulator layer 246 on at least the sidewalls of the patterned trench opening(s) 244. In selected embodiments, the insulator layer 216 may be formed by depositing a conformal dielectric liner layer on the backside surface 201 of the substrate 202 and on the bottom and sidewall surfaces of the trench opening(s) 244 using CVD, PECVD, PVD, ALD, or any combination(s) of the above. In selected embodiments, the insulator layer 246 may be formed by a low temperature PECVD or ALD process to a predetermined final thickness in the range of 1-500 Angstroms (e.g., 5-30 Angstroms), though other thicknesses may be used. A suitable dielectric material for the insulator layer 246 is silicon oxide, silicon nitride, silicon oxynitride, or the like. As formed, the insulator layer 246 will electrically isolate the finally formed TSV structure from the semiconductor substrate 202.

FIG. 11 illustrates processing of the semiconductor structure 11 subsequent to FIG. 10 after selectively etching contact openings to expose the peripheral end portions of the conductor fingers 222, 231-236. While any selective etch process may be used, in selected embodiments, one or more directional plasma etch processes may be applied to remove the insulator layer 246 (and any underlying insulator layer 216) from horizontal surfaces on the substrate 202 and the conductor fingers 222, 231-236 at the bottom of the opening 248, while leaving substantially intact the insulator layer 246 formed on vertical sidewall surfaces of the opening 248. The result of the plasma etch process(es) is to expose the barrier liner layer 222 formed on the peripheral end portions of the conductor fingers 231-236.

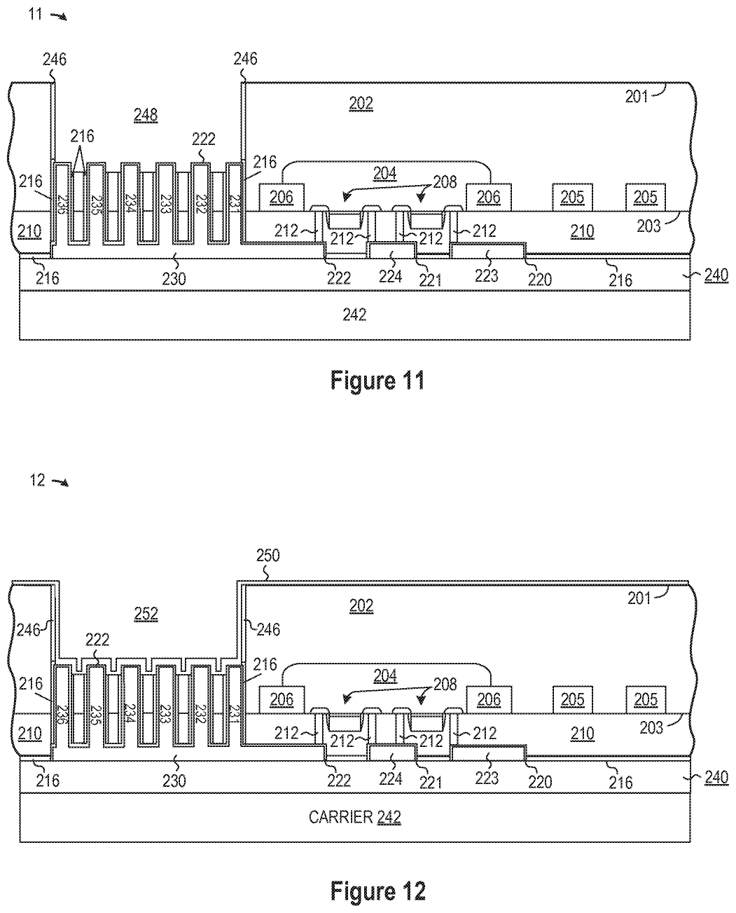

FIG. 12 illustrates processing of the semiconductor structure 12 subsequent to FIG. 11 after forming one or more barrier and/or seed layers 250 in the trench opening(s) 252 with one or more suitable conductor materials. In selected embodiments, a first barrier layer 250 may be formed by depositing one or more conductive metal barrier layers as a liner layer 250 (e.g., Co, Ru, Ta, TaN, RuN, In₂O₃, WN, TiN, RuTaN, etc.) in the metal trench opening(s) 252 using CVD, PECVD, PVD, ALD, MBD, or any combination(s) thereof to a predetermined thickness in the range of 200-1000 Angstroms (e.g., 500-600 Angstroms), though other materials and thicknesses may be used. As formed, the metal barrier liner layer 250 conformally covers the semiconductor structure 12, including the exposed peripheral end portions of the conductor fingers 222, 231-236 and on the bottom and sidewall surfaces of the trench opening(s) 252. On the metal barrier liner layer 250, one or more seed layers (not shown) of conductive metal material (e.g., copper) may be formed using CVD, PECVD, PVD, ALD, MBD, or any combination(s) thereof to a predetermined thickness in the range of 50-1000 Angstroms (e.g., 500-600 Angstroms).

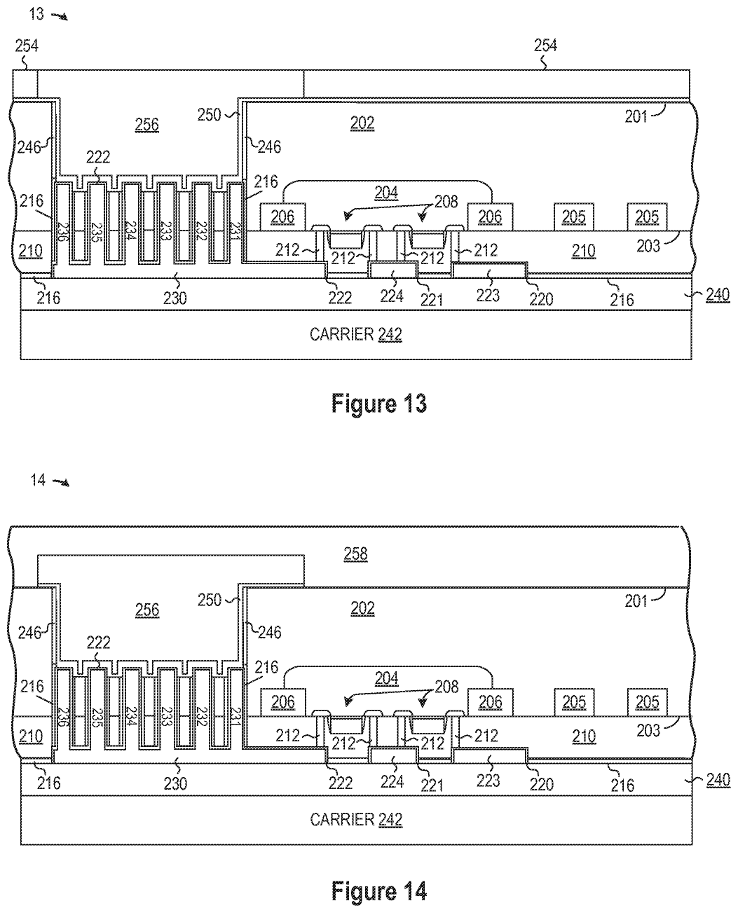

FIG. 13 illustrates processing of the semiconductor structure 13 subsequent to FIG. 12 after forming a patterned infill mask 254 with an opening formed over the trench opening(s) 252 where the TSV structure is to be formed. In selected example embodiments, the infill mask 254 may be formed by patterning a layer of polymer, photoresist, or other appropriate lift-off mask. With the patterned infill mask 254 in place, one or more metal-based layers 256 of suitable conductor material (e.g., copper) are deposited to overfill the trench opening(s) 252 and the infill mask 254 using CVD, PECVD, sputtering, PVD, electro-plating, electro-less plating, or the like. Subsequently, a CMP process removes the copper extending above the top of the infill mask 254 and leaves metal-based layers to define one or more relatively small aspect ratio TSV structures 256 to extend through the wafer substrate 202 for thermo-electrical contact with the exposed small diameter TSV conductor structures 222, 230-236. When the patterned infill mask 254 is subsequently removed or stripped, the underlying barrier and/or seed layers 250 may also be removed from the backside surface 201 of the substrate 202, such as by applying one or more wet etch processes that are selective to the metal-based layers 256.

FIG. 14 illustrates processing of the semiconductor structure 14 subsequent to FIG. 13 after forming a planarized passivation layer 258 to protect the underlying TSV structure 256. As will be appreciated, the planarized passivation layer 258 may be formed using any desired technique, such as by depositing and polishing a dielectric or polymer passivation layer or stack to cover and protect the underlying TSV structure 256 and backside surface 201 of the substrate 202. As will be appreciated, photolithographic processes may be applied to the planarized passivation layer 258 to open contacts to the TSV structures 256 when performing copper pillar processing. Finally, the thin silicon wafer structure is de-bonded from the glass temporary carrier 242.

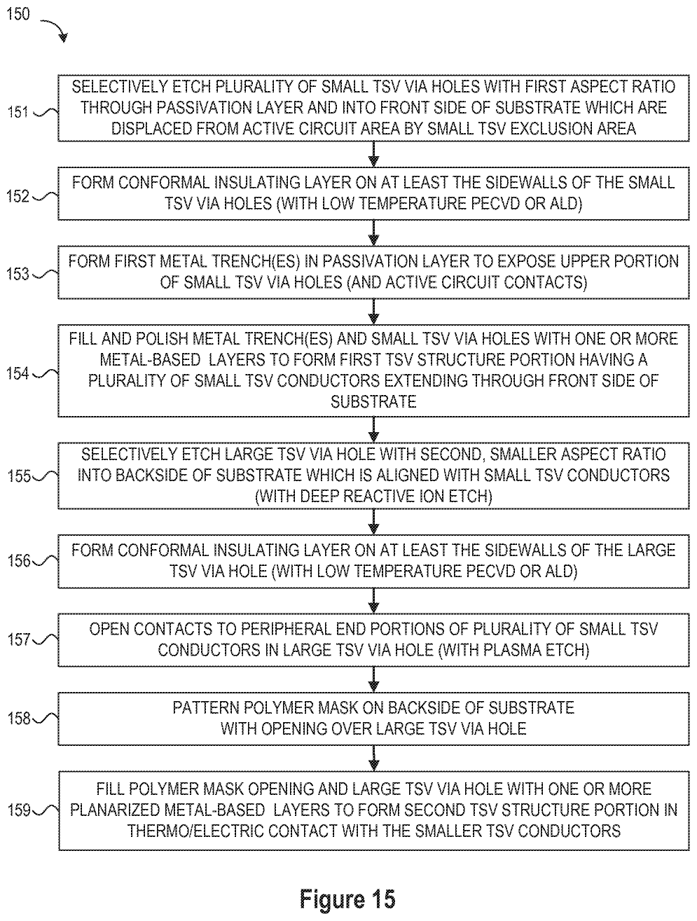

Turning now to FIG. 15, there is shown an example process flow diagram of a fabrication sequence 150 for fabricating a TSV structure in accordance with selected embodiments of the present disclosure. As shown, the process begins at step 151 after forming transistor devices and/or circuitry in one or more active circuit areas of a semiconductor/wafer substrate which are encapsulated or covered by a first passivation layer. At this stage, a plurality of small TSV via holes having a first aspect ratio are selectively etched through the passivation layer and into the front side of the substrate, such as by using photolighography and anisotropic dry etching to define a pattern of holes in matrix pattern, where each TSV via hole has a diameter that is a predetermined fraction (e.g., 1/10) of the TSV design rule. For example, with an aspect ratio of 10, the depths of the small TSV via holes are around 10 times as deep as the diameter. In various embodiments, the size and the number of the small TSV via holes can be varied depending on the requirement of the TSV conductivity. By virtue of forming the plurality of small TSV via holes (and subsequently formed small TSV conductors) through the front side of the substrate, the TSV via holes may be displaced from the active circuit areas by a small TSV exclusion area or distance which extends from the closest small TSV conductor by a distance that is approximately twice the diameter of the small TSV via hole. As a result, the finally formed small TSV conductors can be located much closer to the active circuit area than a conventional TSV structure formed with a larger diameter.

At step 152, a conformal insulating layer is formed on at least the sidewalls of the small TSV via holes. For example, a layer of silicon oxide, silicon nitride, silicon oxynitride may be formed with a low temperature PECVD or ALD process over the entire surface of the semiconductor/wafer substrate and inside the small TSV via holes to electrically isolate the subsequently formed small TSV conductors from the semiconductor/wafer substrate.

At step 153, one or more metal trench openings may be formed in the passivation layer to expose an upper portion of the small TSV via holes. For example, a first metal trench pattern may be formed over the passivation layer to selectively etch a front side TSV opening over the upper portion of the small TSV via holes, alone or in combination with one or more first metal trench openings which overlap with and expose one or more contact vias connected to the active circuits or transistor devices formed on the semiconductor/wafer substrate.

At step 154, the metal trench openings and small TSV via holes are filled by depositing one or more metal-based layers and then polishing or planarizing the metal-based layer(s) to form a first TSV portion. For example, the trench openings and small TSV via holes may be sequentially filled with a barrier metal layer, copper seed layer, and copper fill layer, followed by CMP planarization. The resulting first TSV structure portion has a plurality of small TSV conductor fingers extending through the front side or surface of the semiconductor/wafer substrate which are isolated from the substrate by the previously-formed conformal insulating layer. At this point, additional back end of line (BEOL) processing may be performed to form one or more metal interconnect layers and passivation layers on the front side of the semiconductor/wafer substrate, including at least a first dielectric passivation layer formed over the first TSV structure portion. In addition, the wafer may be configured for backside processing such as by bonding the front side of the semiconductor/wafer substrate to a glass carrier.

At step 155, backside processing of the wafer may begin by selectively etching one or more large TSV via holes into the backside of the semiconductor/wafer substrate. During backside processing, alignment marks formed on the front side of the substrate during the formation of transistors may be used to align backside TSV formation. As formed, the large TSV via hole(s) have a second, larger aspect ratio and are aligned for contact with the small TSV conductors. For example, the large TSV via hole(s) may be formed by forming a patterned etch mask and applying a deep reactive ion etch to etch into the semiconductor substrate material. The depth of the large TSV via hole(s) is controlled to expose peripheral end portions of the small TSV conductors (including any remaining conformal insulating layer formed at step 152).

At step 156, a conformal insulating layer is formed on at least the sidewalls of the one or more large TSV via holes. For example, a layer of silicon oxide, silicon nitride, silicon oxynitride may be formed with a low temperature PECVD or ALD process over the entire backside surface of the semiconductor/wafer substrate and inside the large TSV via hole(s) to provide electrical isolation for the subsequently formed TSV structure. As formed, the conformal insulating layer may also cover the bottom of the large TSV via hole(s), including any peripheral end portions of the small TSV conductors (including any remaining conformal insulating layer formed at step 152) exposed thereby.

At step 157, contact openings are formed at the bottom of the large TSV via hole(s) to expose the peripheral end portions of the small TSV conductors. For example, a plasma etch process may be performed to open contacts to the front side small TSV conductors. In this way, the plasma etch process removes any conformal insulating layer(s) formed on the exposed peripheral end portions of the small TSV conductors.

At step 158, a polymer mask (or other suitable mask layer) is formed on the backside of the semiconductor/wafer substrate and patterned to define an opening over the one or more large TSV via holes. In selected embodiments, the defined opening in the polymer mask is larger than the width of the large TSV via hole(s), thereby exposing a portion of the backside surface of the semiconductor/wafer substrate around the large TSV via hole(s).

At step 159, the polymer mask opening and large TSV via hole(s) are filled by depositing one or more metal-based layers and then polishing or planarizing the metal-based layer(s) to form a second TSV structure portion in thermo-electric contact with the smaller TSV conductors of the first TSV structure portion. For example, the polymer mask opening and large TSV via hole(s) may be sequentially filled with a barrier metal layer, copper seed layer, and a copper fill layer, followed by CMP planarization. As will be appreciated, the copper fill layer may be formed as desired, such as by using electroplated or CVD copper to fill the conductive layer directly on the barrier metal layer or on the copper seed layer/barrier metal layer. The resulting second TSV structure portion may have a single, larger conductor that is buried in the substrate and isolated therefrom by the previously-formed conformal insulating layer. By forming the second TSV structure portion to be buried by a minimum specified depth below the front side surface of the substrate so that the second TSV structure portion does not extend through or near the front side or surface of the semiconductor/wafer substrate, the second TSV structure portion does not create structural stress on the front side or surface of the substrate which would require a larger exclusion area or distance from the active circuit area. At this point, the patterned polymer mask (and any underlying seed copper layer and barrier metal layer) may be removed to expose the backside surface of the semiconductor/wafer substrate, and one or more polymer coating layers may be formed over the backside surface to insulate the TSV structure and substrate. Additional photolithographic processing and contact formation may be applied to connect the TSV structure to external electro-thermal conductors (e.g., copper pillars), after which the semiconductor/wafer substrate may be de-bonded or separated from any glass carrier formed on the front side surface.

As shown above, the fabrication sequence 150 is described with reference to specified TSV structure having first and second TSV structure portions, where the first TSV portion includes multiple small TSV conductor fingers extending through a first topside surface of the substrate by a minimum specified depth, and where the second TSV portion includes a single wider TSV conductor extending from a first backside surface of the substrate to make thermo-electrical contact with the first TSV portion. However, it will be appreciated that various benefits of the present disclosure may also be obtained from forming TSV structures with other configurations and dimensions than disclosed herein to provide small-diameter TSV conductors at the front side or surface of the substrate which reduce the structural stress on the front side or surface of the substrate which would otherwise require a larger exclusion area or distance from the active circuit area.

By now it should be appreciated that there is provided herein an integrated circuit device and associated process for fabricating a through semiconductor via (TSV) conductor structure in a semiconductor substrate. In the disclosed integrated circuit device, there is formed a semiconductor substrate (e.g., a bulk or SOI substrate) having a backside surface and an active device surface on which one or more active circuits are formed with at least a first conductive interconnect layer electrically connected to the one or more active circuits. The integrated circuit device also includes a through semiconductor via (TSV) conductor structure that is electrically connected to the first conductive interconnect layer and formed in the semiconductor substrate to extend between at least the active device surface and the backside surface. In particular, the TSV conductor structure includes one or more of relatively small diameter conductive vias which may have a predetermined aspect ratio (e.g., 10) to extend through the active device surface and into the semiconductor substrate by a predetermined depth. In selected embodiments, the small diameter conductive vias are formed in the semiconductor substrate as a matrix of evenly spaced conductor fingers extending from the first conductive interconnect layer and through the active device surface and into the semiconductor substrate. The TSV conductor structure also includes one or more relatively large diameter conductive vias formed to extend from the one or more relatively small diameter conductive vias and through the backside surface. The conductive vias may be formed with a plurality of metal-based layers, such as, for example, a metal barrier layer and an electroplated copper fill layer which are planarized with a chemical mechanical polish process. In selected embodiments, the integrated circuit device includes a pre-metal dielectric layer formed over the active device surface to cover the active circuits such that the one or more relatively small diameter conductive vias are formed to extend through the pre-metal dielectric layer and active device surface and into the semiconductor substrate. The integrated circuit device may also include a dielectric liner layer formed to surround the TSV conductor structure and isolate the TSV conductor structure from the semiconductor substrate. As disclosed, the TSV conductor structure may be spaced apart from the active circuits by a spacing distance that is less than the diameter of the one or more relatively large diameter conductive vias. In selected embodiments, the TSV conductor structure may be spaced apart from the active circuits by a spacing distance that is approximately twice the diameter of the relatively small diameter conductive via(s).

In another form, there is provided an integrated circuit device and method for making same. In the disclosed methodology, a substrate is provided that has a first surface on which one or more active circuits are formed, and a second surface opposite the first surface. On the first surface, one or more first conductive vias are formed to extend through the first surface and partially through the substrate by a predetermined depth, where each first conductive via has a first diameter. In selected embodiments, the first conductive vias may be formed by selectively etching one or more first patterned via holes through the first surface of the substrate and partially through the substrate having a first aspect ratio. On one or more sidewall surfaces of the first patterned via holes, a first conformal isolation dielectric layer may be formed, followed by forming or depositing one or more metal-based layers (e.g., a first barrier metal layer, metal seed layer, and electroplated copper) on the first conformal isolation dielectric layer to fill the one or more first patterned via holes, thereby forming the one or more first conductive vias. On the second surface, one or more second conductive vias are formed to extend through the second surface to make electrical contact with the one or more first conductive vias, where each second conductive via has a second, larger diameter. In selected embodiments, the second conductive vias may be formed by selectively etching one or more second via holes through the second surface of the substrate and partially through the substrate to extend past peripheral end portions of the one or more first conductive vias, where the second via holes have a second, different aspect ratio. On one or more sidewall surfaces of the second via holes, a second conformal isolation dielectric layer may be formed, followed by forming or depositing one or more metal-based layers (e.g., a barrier metal layer, metal seed layer, and electroplated copper) on the second conformal isolation dielectric layer to fill the one or more second via holes and to make electrical contact with the peripheral end portions of the one or more first conductive vias, thereby forming the one or more second conductive vias. Prior to forming the metal-based layers, a plasma etch or deep reactive ion etch may be applied to remove one or more isolation dielectric layers from the peripheral end portions of the one or more first conductive vias exposed by the one or more second via holes. When forming the metal-based layers on the second conformal isolation dielectric layer, a first barrier metal layer is formed on one or more bottom and sidewall surfaces of the one or more second via holes, followed by forming a metal seed layer on the first barrier metal layer and on one or more bottom and sidewall surfaces of the one or more second via holes, forming a patterned polymer mask with a mask opening formed on the first surface of the substrate which exposes the one or more second via holes, forming electroplate or CVD copper on the metal seed layer to fill the one or more second via holes and the mask opening, and polishing the copper, metal seed layer, and first barrier metal layer to be substantially coplanar with the patterned polymer mask, thereby forming the one or more second conductive vias. With this arrangement, the first conductive vias may be spaced apart from the active circuits by a lateral spacing distance that is less than the second, larger diameter of the one or more second conductive vias. Stated differently, the first conductive vias may be spaced apart from the active circuits by a lateral spacing distance that is approximately twice the first diameter of the one or more first conductive vias.

In yet another form, there is provided an integrated circuit apparatus and method of fabricating same. In the disclosed integrated circuit apparatus, a substrate includes an active circuit and interconnect layer provided on a first surface of the substrate and covered with one or more interlayer dielectric layers. In addition, the integrated circuit apparatus includes one or more first vias electrically connected to the active circuit and interconnect layer and comprising electroplated or CVD copper formed on a metal barrier layer and insulated from the substrate by an insulating layer, each first via having a first diameter and extending from the one or more interlayer dielectric layers through the first surface of the substrate and partway through the substrate by a predetermined depth. The integrated circuit apparatus also includes a second via comprising electroplated or CVD copper formed on a metal barrier layer and insulated from the substrate by an insulating layer, the second via having a second, larger diameter and extending from a surface of the substrate opposite the active circuit to make electrical contact with the one or more first vias. With this configuration, the one or more first vias are spaced apart from the active circuit by a lateral spacing distance that is less than the second, larger diameter or approximately twice the first diameter.

Although the described exemplary embodiments disclosed herein are directed to various semiconductor device structures and methods for making same using through silicon via structures with reduced stress proximity effects, the present invention is not necessarily limited to the example embodiments which illustrate inventive aspects of the present invention that are applicable to a wide variety of fabrication processes and/or structures. Thus, the particular embodiments disclosed above are illustrative only and should not be taken as limitations upon the present invention, as the invention may be modified and practiced in different but equivalent manners apparent to those skilled in the art having the benefit of the teachings herein. For example, while the active circuit areas are illustrated with simplified transistor devices, this is merely for convenience of explanation and not intended to be limiting and persons of skill in the art will understand that the principles taught herein apply to other devices and circuits. Moreover, the thicknesses, depths, and other dimensions of the described layers and openings may deviate from the disclosed ranges or values. In addition, the terms of relative position used in the description and the claims, if any, are interchangeable under appropriate circumstances such that embodiments of the invention described herein are, for example, capable of operation in other orientations than those illustrated or otherwise described herein. The term “coupled,” as used herein, is defined as directly or indirectly connected in an electrical or non-electrical manner. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A semiconductor device comprising:
a TSV structure extending through a bottom surface of the semiconductor device into the semiconductor device in a vertical direction perpendicular to the bottom surface; and
a transistor device formed on a surface of a well region opposite to the bottom surface, wherein
the TSV structure comprises a large diameter TSV portion and a small diameter TSV portion above the large diameter TSV portion, the small diameter TSV portion comprising a first conductor finger which is smaller in diameter than the large diameter TSV portion; and
wherein
a first portion of a top end of the large diameter TSV portion is in contact with a bottom end of the first conductor finger, and a second portion of the top end of the large diameter TSV portion is in contact with a first conductive region laterally proximate to the first conductor finger, wherein
the first conductor finger extends away from the large diameter TSV portion in the vertical direction to contact a second conductive region.

2. The semiconductor device of claim 1, wherein the first conductive region is a p-type conductivity region.

3. The semiconductor device of claim 1, wherein the first conductive region is an n-type conductivity region.

4. The semiconductor device of claim 1, wherein the second conductive region is a first metal interconnect.

5. The semiconductor device of claim 4, wherein the small diameter TSV portion comprises a second conductor finger that extends away from the large diameter TSV portion in the vertical direction to contact the second conductive region.

6. The semiconductor device of claim 4, further comprising a second metal interconnect (114) connecting to the transistor device through a contact.

7. The semiconductor device of claim 6, wherein the first metal interconnect and the second metal interconnect each comprise copper.

8. The semiconductor device of claim 6, further comprising a barrier layer comprising a conductor material and lining at least a portion of the large diameter TSV portion.

9. The semiconductor device of claim 8, wherein the barrier layer is selected among the group comprising Co, Ru, Ta, TaN, RuN, In₂O₃, WN, TiN and RuTaN.

10. The semiconductor device of claim 8, wherein the barrier layer is selected among the group comprising Ta and TaN.

11. The semiconductor device of claim 8, wherein the barrier layer comprises TiN.
